(19) United States
(12) Patent Application Publication
(10) Pub. No.: US 2019/0312531 A1
(43) Pub. Date: Oct. 10, 2019

(54) TRANSPARENT ENERGY HARVESTING DEVICE

(71) Applicant: InnovaSonic, Inc., Dublin, CA (US)

(72) Inventor: Boris Kobrin, Dublin, CA (US)

(21) Appl. No.: 16/367,026

(22) Filed: Mar. 27, 2019

Related U.S. Application Data
(63) Continuation of application No. 62/652,887, filed on Apr. 4, 2018.

(51) Int. Cl. H02N 2/18; H02N 1/08; H02N 2/00; H01L 41/113; H01L 41/331; H01L 31/0224; H01L 31/0468; H01L 31/18; H01L 35/32; H01L 35/34; H01Q 1/24; H01Q 1/38; H01Q 1/12; H01Q 1/27; H01Q 21/06

(52) U.S. Cl. CPC H02N 2/18; H01Q 21/062; H02N 2/22; H01L 41/113; H01L 41/331; H01L 31/022466; H01L 31/0468; H01L 31/18; H01L 35/32; H01L 35/34; H01Q 1/248; H01Q 1/38; H01Q 1/1271; H01Q 1/273; H02N 1/08

(57) ABSTRACT

A transparent energy harvesting device includes a transparent substrate and one or more patterned materials with feature sizes less than 10 micron, 5 micron, or even less than 2.5 micron, where such materials are comprised of piezoelectric, photovoltaic or thermoelectric materials.

### 1. CLAIM OF PRIORITY

This Application claims the priority benefit of U.S. Provisional Patent Application No. 62/652,887 filed Apr. 4, 2018, the entire contents of which are incorporated herein by reference for all purposes.

### 2. FIELD OF THE DISCLOSURE

The present disclosure relates to energy harvesting devices and more particularly to transparent energy harvesting devices, which could be integrated with displays, architectural windows, transportation vehicle's windshields, windows, and sunroofs, coverglass of wearable devices, like watches, goggles, glasses, visors, transparent packaging, and many other devices.

### 3. BACKGROUND

Energy harvesting is very attractive, especially for mobile electronics or transportation. It removes the necessity of having an onboard source of power—batteries, or at least reduces their weight.

There are multiple energy harvesting devices known and implemented so far, including photovoltaics (solar cells and ambient-radiation cells), pressure transducers, thermoelectric and pyroelectric systems, magnetic induction devices, and many more.

The essential part of the wearable and mobile electronic devices, like cell phones, tablets, watches is a display, which occupies almost entire surface of the device exposed to light and directional sound. The same is true for transportation vehicles, like cars, planes and boats: essential part of the surface is covered with windshield, windows and sunroof. The problem is that the currently available energy harvesting devices are not transparent, so one can not seamlessly integrate it with display glass or a car windshield without compromising safety, esthetics and functionality.

There has been a push to integrate transparent organic-PV material solar cells with displays and windows, but the efficiency of such device is limited by capabilities of organic-PV material, and currently is less than 7%. What is even more troublesome is transparency of such organic-PV is only 40%.

The same situation is present with transparent organic-piezoelectric materials, which have piezoelectric constant hundreds of pm/V less than opaque ceramic piezoelectric materials.

The solution we propose lies in creating energy harvesting transparent devices based on opaque high-efficiency materials, which are micro- or nanopatterned to provide high transparency and invisibility to the human eye.

### 4. BRIEF DESCRIPTION OF THE DRAWINGS

Various aspects of the present disclosure will become apparent upon reading the following detailed description and upon reference to the accompanying drawings in which:

FIG. 1A-1C is a schematic diagram illustrating an example of energy harvesting devices integrated with car's windshield, iwatch and glasses

FIGS. 2A-2C are schematic diagrams illustrating examples of transparent microstructured piezoelectric transducers in accordance with various aspects of the present disclosure.

FIG. 3 is a cross-sectional schematic diagram of a thin film stack structure for a transparent microstructured piezoelectric transducer in accordance with certain aspects of the present disclosure.

FIG. 4 is a cross-sectional schematic diagram illustrating a patterned thin film stack for a transparent microstructured piezoelectric transducer after a lift-off process according to an aspect of the present disclosure.

### 5. DETAILED DESCRIPTION

Although the following detailed description contains many specific details for the purposes of illustration, anyone of ordinary skill in the art will appreciate that many variations and alterations to the following details are within the scope of the invention. Accordingly, the aspects of the disclosure described below are set forth without any loss of generality to, and without imposing limitations upon, the claimed invention.

In the following detailed description, reference is made to the accompanying drawings, which form a part hereof, and in which is shown by way of illustration specific embodiments in which the invention may be practiced. In this regard, directional terminology, such as “top,” “bottom,” “front,” “back,” “first,” “second,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

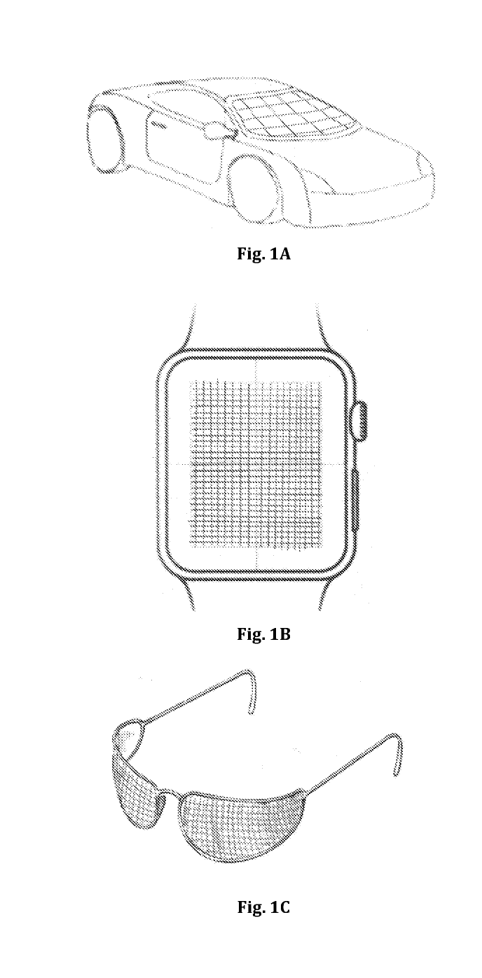

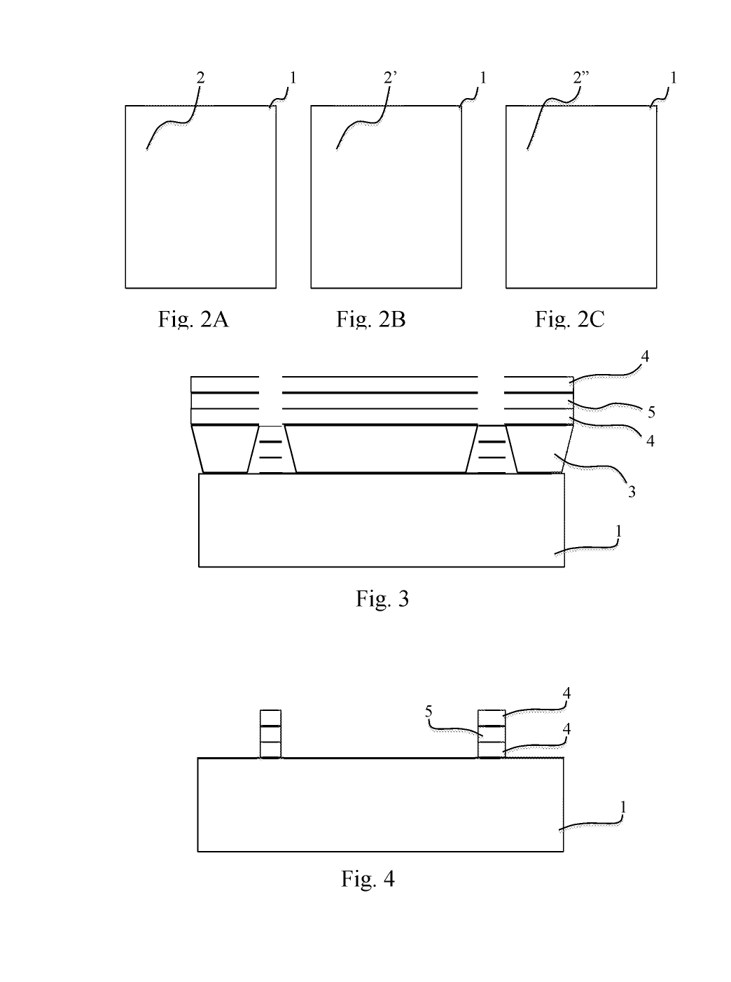

Aspects of the present disclosure include transparent energy harvesting devices and method of their manufacturing. An examples of such energy harvesting devices integrated in commercial products are shown on FIG. 1A (car's windshield), FIG. 1B (wearable electronic device—iwatch), and FIG. 1C (sunglasses). Energy harvesting devices described in this patent may include a micro- or nano-structured mesh (2) as in FIG. 2A or a grating (2′), as in FIG. 2B, or an array (2″), as in FIG. 2C on the surface of a substrate (1), for example glass or polymer film. Obviously, the pattern is not limited to simple geometries, and can be done with variety of different designs. The criteria of transparency for such transducers could be met by optimizing a ratio of microstructure to an open area of the substrate. The criteria of visibility (unobstructed view) can be met by optimizing the feature size of the structure to be below recognition of a human eye at the required distances. That minimum feature size is usually less than 10 micron, though for the most demanding applications and good human vision, it could be less than 5 micron or even 2.5 micron.

A micro- or nano-structured ultrasonic or pressure transducers, which can harvest energy of human touch, wind/incoming air pressure, rain drops, and sound waves, mechanical deformation, could be made of a piezoelectric material with electrodes, micro-or nano-structured to be very transparent and invisible to the eye. Thus it can be seamlessly integrated with display glass cover or car's windshield, plastic films, etc. Energy harvesting by transparent ultrasonic or pressure transducers integrated in display's cover could harvest energy of person voice, ambient sounds or finger touch and palm's holding pressure.

Another possibility is to harvest vibrations and movements of the body parts or transportation vehicles using kinetic energy transducers, for example based on Coulomb Force Parametric Generators (CFPG) that correspond to displacement electrostatic generator type. Such kinetic transducer can be fabricated using well-known micro-electro-mechanical systems (MEMS) technology. Such MEMS devices could be fabricated on transparent substrate and have lateral dimensions less than 10 micron, or 5 micron, or even 2.5 micron, so be invisible to the human eye and leave the substrate transparent.

Another embodiment includes harvesting electromagnetic radiation of visible and UV spectrum (solar or ambient light) using photovoltaics material micro- or nano-structured with feature sizes providing high transparency and invisibility to the eye to be used in display and windows/windshield products.

Another embodiment includes harvesting electromagnetic radiation of infrared (thermal) spectrum using thermocouple, comprising a p-type and n-type semiconductor connected electrically in series and thermally in parallel. Such thermoelectric cells could be patterned on the transparent substrate with features small enough to be invisible and preserve high transparency of the substrate. Thermal energy may come from the sunlight, other ambient heat generators, and human body.

And yet another embodiment includes harvesting electromagnetic radiation of RF radiation. In cities and very populated areas there is a large number of potential RF sources: broadcast radio and tv, mobile telephony, wireless networks, etc. A device can collect all these disparate sources and convert them in useful energy. The conversion is based on a rectifying antenna (rectenna), constructed with a Schottky diode located between the antenna dipoles. One can fabricate an array of transparent micro- or nanostructured rectennas on transparent substrate.

Aspects of the present disclosure include, but are not limited to, the following embodiments.

### Embodiment-I

A piezoelectric material is sandwiched between 2 electrodes, e.g., as shown in FIG. 3. Both, a piezoelectric thin film (5) and electrodes (4), could be patterned on the substrate surface to yield a very transparent and invisible-to-the-eye device. In an alternative implementation, one or both electrodes could be deposited as a continuous layer of transparent conductive material, and only piezoelectric material would be patterned. Such transparent conductive material could be, e.g., Indium-Tin Oxide (ITO) or another transparent conductive oxide (TCO), or transparent organic conductors, or graphene, or silver nanowires or nanoparticles. Obviously, while the bottom electrode can be metal material, the top electrode must be transparent conductor.

Piezoelectric material (for example, lead zirconate titanate (PZT), lead lanthanum zirconate titanate (PLZT), barium titanate, ammonium dihydrogen phosphate (ADP), etc.), and thin metal film again (for example, silver). Those materials could be deposited from the vapor phase using sputtering or evaporation, or in the liquid form of suspension particles (nanoink) or in the Sol-Gel form by spinning, dip-coating, slot-die coating, xerography, gravure, screen printing, inkjet printing, microcontact printing, aerosol deposition or others).

The substrate could be additionally pre-patterned with hydrophobic (superhydrophobic) and hydrophilic (superhydrophilic) areas to enhance resolution or control adhesion or structure of deposited materials.

In order to reduce visibility of piezoelectric or conductive features to the human eye, e.g., from a distance of a couple of feet (for a car windshield, for example) the pattern preferably has features with a linewidth of less than 5 micron, more preferably less than 3 micron linewidth, and ideally less than 2 micron linewidth.

The deposition may be done according to any desired pattern (for example, a one-dimensional grating of straight or curved lines or a two-dimensional mesh or an array of small islands, etc.).

The pattern could be uniform/continuous over the surface or divided to multiple areas individually addressable by application of ultrasonic power in order to be able to forward power only to the area where cleaning is necessary.

### Embodiment-II

A substrate, for example glass, is coated with the following thin film stack using, for example, sputtering technique: a thin metal film (for example, silver), a layer of piezoelectric material (for example, PZT), and another thin metal film (for example, silver). Then this stack is then patterned using a suitable patterning technique, for example, laser ablation. Alternatively one can use any of the following patterning techniques followed by material etching: electron-beam lithography, ultraviolet (UV) lithography, nanoimprint lithography, optical lithography, interference lithography, laser scanning lithography, self-assembly, etc. The type of lithography may be chose based on considerations of cost, scalability, and resolution of patterning required for achieving a specific optical, mechanical and cosmetic performance of the device being fabricated.

### Embodiment-III

As shown in FIG. 3, a substrate is coated with a photosensitive layer (3), e.g., a photoresist (or multiple layers of photoresist). Then the photosensitive layer (3) is patterned using optical lithography which assures reentrant profile of the patterned photoresist features. The following stack is then deposited on the patterned photosensitive layer (3): a first thin metal film (4), for example, silver, a piezoelectric material (5), for example, PZT, and a second thin metal film (4), for example, silver. Finally a lift-off process is done by dissolving the photosensitive layer (3) to yield a microstructured metal stack on the substrate surface, as shown in FIG. 4. The same thin film stack could be used as a transparent conductor electrode for touch sensor, and as a transducer for energy harvesting.

### Embodiment-IV

In this embodiment, a substrate is coated with a polymer layer, which is then patterned, e.g., using a nanoimprint method. Then, the following materials stack is deposited in protrusions formed as a result of nanoimprint patterning: a metal layer, a piezoelectric material layer, and finally another metal layer. Alternatively, just metal and piezo-electric material if an interdigitated design is used.

### Embodiment-V

In this embodiment, a substrate with conductive layer is patterned with superhydrophobic material (e.g., a self-assembled monolayer) using lithography and lift-off, laser ablation or direct microcontact printing. Then piezoelectric material (PZT) is deposited and annealed; PZT on top of superhydrophobic material can't be crystalized and remains amorphous, thus could be removed during lift-off process.

### Embodiment-VI

In this embodiment, a polymer material is deposited on the substrate using inkjet printing such as it creates a pattern of lines or curves with narrow gaps between them. Moreover, the substrate is pre-treated with hydrophobic or superhydrophobic agents to have a low surface energy, so that the lines or curves of polymer form a re-entrant profile with the substrate surface. Then metal and other functional materials, like piezoelectric or semiconductor can be deposited in the gaps (grooves); and finally the polymer is dissolved (lifted off) from the substrate.

### Embodiment-VII

In this embodiment, a substrate is coated with a photosensitive layer, e.g., a photoresist (or multiple layers of photoresist). Then the photosensitive layer is patterned using an optical lithography that assures a reentrant profile of the patterned photoresist features. The pattern includes interdigitated lines or trenches. The substrate is then coated with metal material. Then a lift-off process is done by dissolving photosensitive layer (or layers) to yield a microstructured metal stack on the substrate surface. Finally, a transparent piezoelectric film , for example polyvinylidine fluoride—PVDF films (Kynar® Film & Solef® Film or others), is laminated to the substrate over the patterned electrodes on the substrate surface with an impedance matching material sandwiched between the piezoelectric film and the electrode pattern.

### Embodiment-VIII

In this embodiment capacitive micromachined ultrasonic transducer (cMUT) is build on a glass substrate using standard micro-electro-mechanical-systems (MEMS) technology, for example using sacrificial release process for fabricating a membrane. Such transducers would have a lateral features no larger than 10 micron, or 5, or 2.5 micron and can be integrated with wearable display to harvest energy for watch operation using movement of the arm.

### Embodiment-IX

In this embodiment bulk micromachining technique and piezoelectric layer is used to create a transparent piezoelectric MEMS energy harvesting device. Methods described in embodiments I-VII are complemented by bulk micromachining methods of releasing of bending/flexing arm, which consist of piezoelectric layer.

### Embodiment-X

The concepts similar to embodiments I-VII could be used to fabricate invisible and transparent solar cells on display glass or car window for energy harvesting purposes, if piezoelectric material is replaced with a photovoltaic material, like Si, poly-Si, SIGS, and others. Obviously, top electrode must be transparent conductor, for example, ITO or graphene, or silver nanowire, and can be deposited either on top of light absorber material during a masked by photoresist multi-stack deposition process, or as a continuous layer over entire substrate.

### Embodiment-XI

The concepts similar to embodiments I-VII could be used to fabricate invisible and transparent Infrared or thermal energy harvesting device on display glass or car window, if piezoelectric material is replaced with a thermocouple stack of layers. A thermoelectric generator basically consists of a thermocouple, comprising a p-type and n-type semiconductor connected electrically in series and thermally in parallel. The thermogenerator (based on the Seebeck effect) produces an electrical current proportional to the temperature difference between the hot and cold junctions. An electrical load is connected in series with the thermogenerator creating an electric circuit. The Seebeck coefficient is positive for p-type materials and negative for n-type materials. The heat that enters or leaves a junction of a thermoelectric device has two reasons: 1) the presence of a temperature gradient at the junction 2) the absorption or liberation of energy due to the Peltier effect.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

1. A transparent energy harvesting device, comprising:
a transparent substrate and
a one or many patterned materials formed on essentially an entire transparent substrate surface, including a central area of the transparent substrate.

2. The device of claim 1 wherein the patterned materials have features characterized by a linewidth less than 10 microns.

3. The device of claim 1 wherein the patterned materials have features characterized by a linewidth less than 5 microns.

4. The device of claim 1 wherein the patterned materials have features characterized by a linewidth less than 2.5 microns.

5. The device of claim 1 wherein patterned materials comprised of piezoelectric layer and one or two conductive layers

6. The device of claim 1 wherein patterned materials comprised of microelectromechanical (MEMS) stack of layers

7. The device of claim 1 wherein patterned materials comprised of photovoltaic material layer and at least one transparent conductive layer

8. The device of claim 1 wherein patterned materials comprised of thermocouple layers stack and two conductive layers

9. The device of claim 1 wherein patterned materials form a rectenna with a Schottky diode located between the antenna dipoles

10. The device of claim 1 wherein a transparent substrate is a display cover glass or plastic

11. The device of claim 1 wherein a transparent substrate is a window, windshield or sunroof of a transportation vehicle on land, sea, air and space

12. The device of claim 1 wherein a transparent substrate is a glass or plastic cover of a lighting device

13. The device of claim 1 wherein a transparent substrate is a transparent packaging material

14. The device of claim 1 wherein a transparent substrate is an ophthalmic glasses, contacts, intraocular lenses, goggles and visors.

15. The device of claim 1 wherein a transparent substrate is a wearable patch

16. A method of fabrication a transparent energy harvesting device, comprised of forming an array of transparent energy harvesting devices across essentially an entire substrate, including a central portion of the substrate, and such devices having elements with a linewidth less than 10 micron.

17. A method according to claim 16 wherein such devices having elements with a linewidth less than 5 micron.

18. A method according to claim 16 wherein such devices having elements with a linewidth less than 2.5 micron.

19. A method according to claim 16 wherein forming the array of transparent energy harvesting devices includes depositing the array of transparent energy harvesting devices by inkjet or microcontact printing.

20. A method according to claim 16 wherein depositing the array of transparent energy harvesting devices is done on pre-patterned substrate with hydrophobic or superhydrophobic and hydrophilic or superhydrophilic areas.

21. A method according to claim 16 wherein forming the array of transparent energy harvesting devices includes nanoimprint lithography with subsequent deposition of conductive and energy harvesting functional layers in a stack and removal of deposited materials from selected portions of a top surface of the stack.

22. A method according to claim 16 wherein forming the array of transparent energy harvesting devices includes optical or electron beam lithography with subsequent development of a pattern in a layer of a photoresist, deposition of a stack of conductive and energy harvesting functional layers, and lift-off of selected portions of the photoresist.

23. A method according to claim 16 wherein forming the array of transparent energy harvesting devices includes optical or electron beam lithography with subsequent development of a pattern in a layer of a Sol-Gel energy harvesting functional material as a part of photoresist material

24. A method according to 16 wherein forming the array of transparent energy harvesting devices includes a process of micro- or nano-pattern transfer from a sacrificial or intermediary substrate
